(19) United States
(12) Patent Application Publication
(10) Pub. No.: US 2002/0074654 A1
(43) Pub. Date: Jun. 20, 2002

(54) Wiring substrate, wiring board, and wiring substrate mounting structure

(75) Inventor: Shinichi Koriyama, Kokubu-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 09/996,349

(22) Filed: Nov. 27, 2001

(30) Foreign Application Priority Data
Nov. 28, 2000 (JP) 2000-361749

(51) Int. Cl. H01L 23/34

(52) U.S. Cl. 257/728

(57) ABSTRACT

In a wiring substrate, a high-frequency component is carried on a dielectric board having a transmission line formed on its surface, a reverse surface of the dielectric board is formed with an opening in a predetermined cross-sectional shape, and a high-frequency connecting pad is formed around the opening. In the wiring board, a dielectric board penetrates a waveguide structure and has its inner wall coated with a conductor, and a high-frequency connecting pad is formed on a surface of the dielectric board. The wiring substrate is placed on the wiring board, and the respective high-frequency connecting pads are electrically connected to each other, to fabricate a module. Even when a low-cost material having a large dielectric loss tangent is used for the wiring board, a high-frequency signal can be prevented from being attenuated.

This application is based on application No. 2000-361749 filed in Japan, the content of which is incorporated hereinto by reference.

### BACKGROUND OF THE INVENTION

1. Field of the Invention

The present invention relates to a wiring substrate used in a microwave region or a millimeter wave region, a wiring board, and a wiring substrate mounting structure.

2. Description of the Related Art

It has been examined whether or not an electric wave is made use of for transmitting information from a microwave region of 1 to 30 GHz to a millimeter wave region of 30 to 300 GHz. An electric wave application system using a millimeter electric wave, for example, a radar between vehicles has been put to practical use.

As an example of electric components using such high frequencies, a wiring substrate accommodating a plurality of chips in its one case is assumed.

FIG. 6 is a schematic sectional view for explaining the structure of such a wiring substrate 60. In FIG. 6, a metal case 61 and a cover 62 form a cavity. A plurality of high-frequency components 63, a connecting substrate 64, and a microstrip line substrate for external matching 65 are accommodated inside the cavity. Reference numeral 66 denotes a matching section for a microstrip line.

The high-frequency components 63 are connected (bonded) to one another by the connecting substrate 64, the microstrip line substrate for external matching 65, and a gold wire W (which may be a gold ribbon). In the matching section 66, the metal case 61 is formed with an opening 67 having a predetermined cross-sectional shape. A dielectric window 68 for hermetic sealing is brazed to the opening 67.

The wiring substrate 60 is mounted on a surface of a wiring board, to fabricate a high-frequency module.

In such a wiring substrate used in high frequencies or a mounting structure of the wiring substrate, a high-frequency signal is not satisfactorily connected between the matching section 66 in the wiring substrate and the wiring board because the frequency is high, and is reflected on the matching section 66. Accordingly, the high-frequency signal is liable to be attenuated.

When a material for the wiring board is a general low-cost material such as a glass epoxy insulating material, it has a large dielectric loss tangent (tan δ), so that the high-frequency signal is also attenuated in the wiring board. Consequently, the wiring board has been conventionally fabricated using a low-loss material having a small dielectric loss tangent, for example, high-purity alumina, resulting in increased cost.

An object of the present invention is to provide a wiring substrate in which a high-frequency signal is hardly attenuated.

Another object of the present invention is to provide, even in a case where a wiring substrate having a high-frequency component carried thereon is surface-mounted on a general low-cost wiring board composed of glass epoxy or the like, a wiring substrate mounting structure in which a high-frequency signal is hardly attenuated.

### BRIEF SUMMARY OF THE INVENTION

The inventors of the present invention have incorporated into a wiring substrate a matching section for a transmission line such as a microstrip line in a wiring substrate to match with the exterior, and further incorporated a waveguide structure which can be coupled to the matching section into a wiring board. They have found that even when a low-cost material having a large dielectric loss tangent is used for the wiring board, a high-frequency signal can be prevented from being attenuated, to make the present invention.

(1) A wiring substrate in the present invention has a dielectric substrate having a high-frequency component and a transmission line formed on its surface. The dielectric substrate is formed with an opening in a predetermined cross-sectional shape, and is coated with a conductor layer around the opening on a reverse surface of the dielectric substrate. The conductor layer is referred to as a “high-frequency connecting pad”. Further, a matching section for high-frequency coupling the transmission line and a waveguide structure connected to the high-frequency connecting pad to each other is formed in the opening. A power pad is formed on the reverse surface of the dielectric substrate.

According to the wiring substrate, the matching section for taking out a signal flowing through the transmission line such as the microstrip line is incorporated into the wiring substrate, thereby making it possible to convert the high-frequency signal into an electromagnetic wave in a waveguide mode and feed the electromagnetic wave to the exterior.

(2) A wiring board according to the present invention has a waveguide structure penetrating a dielectric board from its surface to its reverse surface. The waveguide structure has a predetermined cross-sectional shape, and has its inner wall coated with a conductor. A high-frequency connecting pad composed of a conductor layer is provided around the waveguide structure on the surface of the dielectric board.

(3) A wiring substrate mounting structure according to the present invention is characterized in that a wiring substrate having a high-frequency component carried thereon is placed on a surface of a wiring board, and the high-frequency connecting pad in the wiring substrate and the high-frequency connecting pad in the wiring board are electrically connected to each other.

According to the wiring substrate mounting structure, the wiring substrate and the wiring board are connected to each other through the high-frequency connecting pads respectively formed therein, thereby making it possible to transmit the high-frequency signal by the waveguide mode between the wiring substrate and the wiring board. Even if a material having a small dielectric loss tangent is not used as a material for the wiring board, therefore, it is possible to realize high-frequency transmission having a low loss between the wiring substrates or between the wiring substrate and the external circuit. Further, a low-cost material for the wiring board is used, and quantity production is improved by surface mounting, thereby making it possible to obtain a high-frequency module having good characteristics and low in cost.

(4) A wiring substrate mounting structure according to the present invention is characterized in that a plurality of wiring substrates having high-frequency components respectively carried thereon are mounted on a surface of a wiring board, and another wiring substrate is mounted on a reverse surface of the wiring board. The plurality of wiring substrates on the surface are respectively coupled to a plurality of waveguide structures formed in the wiring board, and the wiring substrate on the reverse surface is coupled to the waveguide structures.

According to the wiring substrate mounting structure, a high-frequency signal in the wiring substrate can be transmitted to the other wiring substrate via the waveguide structure formed in the wiring board and the wiring substrate on the revere surface.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is a schematic plan view for explaining the structure of a wiring substrate according to an embodiment of the present invention, FIG. 1B is a cross-sectional view taken along a line X-X, and FIG. 1C is a schematic bottom view;

FIG. 2A is a schematic plan view for explaining the structure of a wiring board according to an embodiment of the present invention, and FIG. 2B is a cross-sectional view taken along a line Y-Y;

FIG. 3 is a schematic sectional view for explaining a mounting structure of a wiring substrate according to an embodiment of the present invention;

FIG. 4 is a schematic sectional view for explaining a mounting structure of a plurality of wiring substrates according to an embodiment of the present invention;

FIG. 5 is a schematic sectional view for explaining another structure of a wiring substrate according to an embodiment of the present invention; and

FIG. 6 is a schematic sectional view for explaining the structure of a conventional wiring substrate.

### DETAILED DESCRIPTION OF THE INVENTION

1. Structure of Wiring Substrate

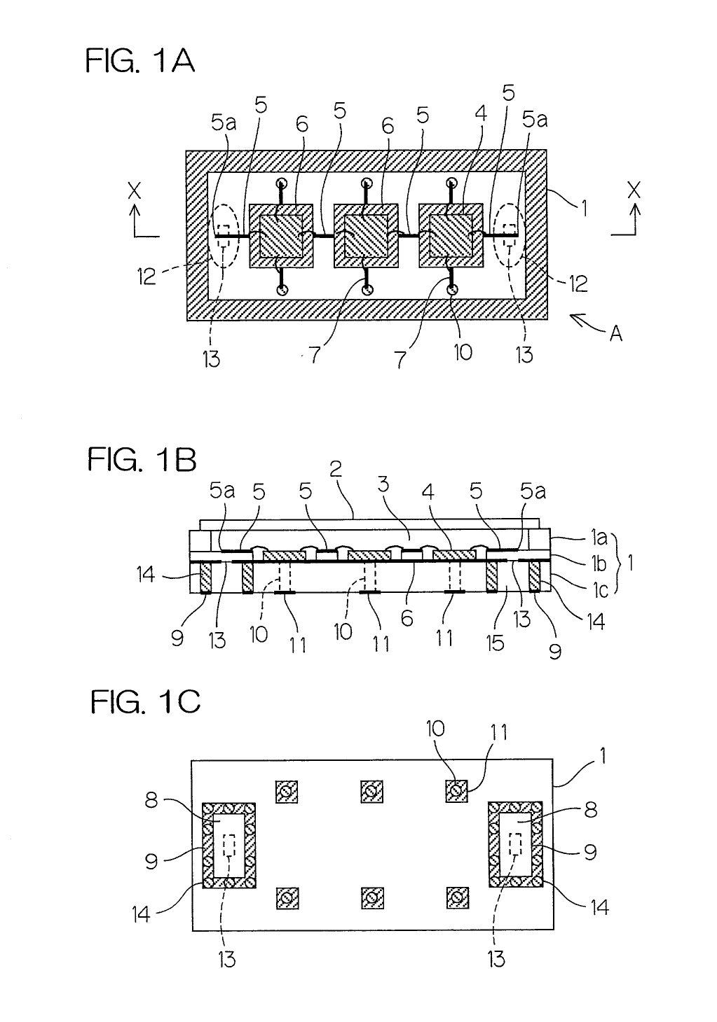

FIGS. 1A to 1C are diagrams for explaining an example of the structure of a wiring substrate A according to the present invention.

As shown in FIGS. 1A to 1C, a wiring substrate A has a dielectric substrate 1 having a stacked structure of dielectric layers 1a, 1b, and 1c. A cover 2 is joined to a surface of the dielectric layer 1a in the dielectric substrate 1, thereby forming a cavity 3 hermetically sealed. A strip conductor 5 for a microstrip line is formed on a surface of the dielectric layer 1b in the dielectric substrate 1. A ground layer 6 for a microstrip line is formed on a surface of the dielectric layer Ic in the dielectric substrate 1. The stripe conductor 5 and the ground layer 6 constitute the microstrip line.

A carrying section on which a high-frequency component is carried is formed on a surface of the ground layer 6, and a high-frequency component 4 is carried thereon. The high-frequency component 4 is coated with a power or control line 7 for feeding power or a control signal to the high-frequency component 4.

A high-frequency connecting pad 9 is formed on a reverse surface of the dielectric substrate 1. A cross-sectional shape of an opening 8 in the high-frequency connecting pad 9 has the same shape as that in cross section of a waveguide structure (described later). In the wiring substrate A shown in FIG. 1, two high-frequency connecting pads 9 for input and output signals are formed. Further, the reverse surface of the dielectric substrate 1 is coated with a power pad 11. The power pad 11 is connected to the power or control line 7 formed on the surface of the dielectric substrate 1 by a via conductor 10.

The wiring substrate A comprises a conversion section 12 for coupling the waveguide structure and the microstrip line formed on the surface of the dielectric substrate 1. The structure of the conversion section 12 is as follows. As shown in FIG. 1B, a slot hole 13 is formed in the ground layer 6. The position where the slot hole 13 is formed is the center of the opening 8 in the high-frequency connecting pad 9 as viewed from the top (see FIG. 1C). As shown in FIG. 1A, an opened end 5a of the stripe conductor 5 constituting the microstrip line is formed at a predetermined position so as to stand face to face with the slot hole 13.

A vertical conductor 14 for connecting the ground layer 6 and the high-frequency connecting pad 9 to each other is formed on the dielectric layer 1c in the dielectric substrate 1. A matching section 15 for achieving impedance matching with a waveguide is formed in a region enclosed by the vertical conductor 14. The conversion section 12 makes it possible to electromagnetically couple the microstrip line and the waveguide structure to each other through the slot hole 13. Beneath the slot hole 13 is filled with dielectric material.

A positional relationship for electromagnetically coupling the slot hole 13 and the stripe conductor 5 to each other is the same as a conversion structure conventionally known. It is described in International Publication WO96/27913, for example. Briefly stated, the opened end 5a of the stripe conductor 5 is formed at a position projecting by a length which is one-fourth the wavelength of a signal from the center of the slot hole 13 as viewed from the top (planview) The slot hole 13 is a long narrow hole which is rectangular, elliptical, for example, and the shape thereof is adjusted by the used frequency and the bandwidth of the frequency. The long diameter of the slot hole 13 is set to a length which is one-half (½) the wavelength of the signal, and the short diameter thereof is set to a length which is one-fifth (⅕) to one-fiftieth (1/50) the wavelength of the signal.

The wiring substrate A having the above-mentioned structure comprises the high-frequency connecting pad 9. Accordingly, the microstrip line in the cavity 3 can be coupled to all waveguide structures. Further, the wiring substrate A has the power pad 11. Accordingly, the wiring substrate can be surface-mounted on a wiring board having a waveguide structure, described later.

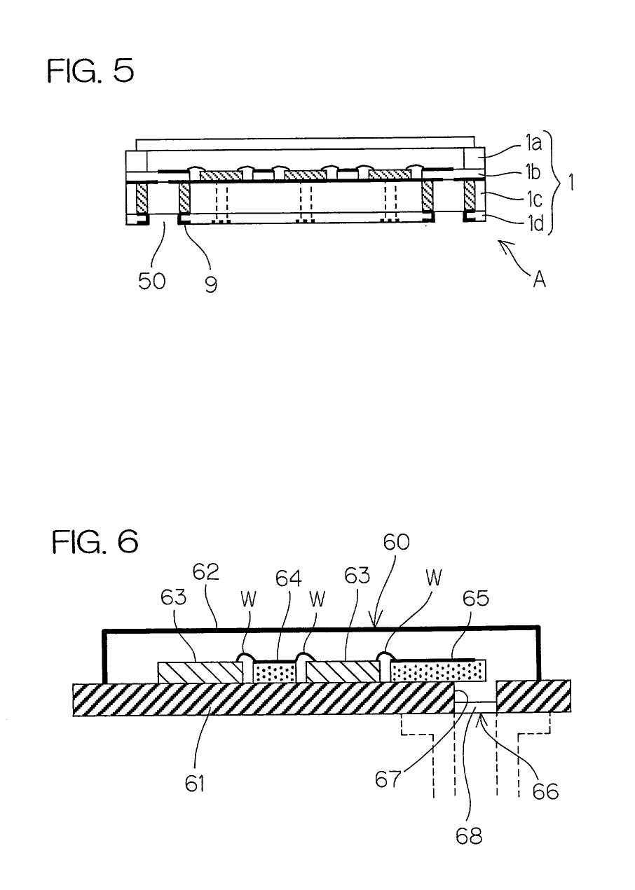

As shown in FIG. 5, a dielectric layer 1d having a waveguide structure 50 having an opening whose inner wall is coated with a conductor layer formed therein may be stacked on a reverse surface of the dielectric boards 1a to 1c in the wiring substrate A. The high-frequency connecting pad 9 is hollowed inward from the reverse surface of the dielectric layer 1d.

According to such a structure, it is possible to increase the thickness of the dielectric substrate 1 to increase the substrate strength without degrading high-frequency characteristics. Further, the number of wiring layers is increased, thereby making it possible to increase the degree of freedom of wiring.

2. Structure of Wiring Board

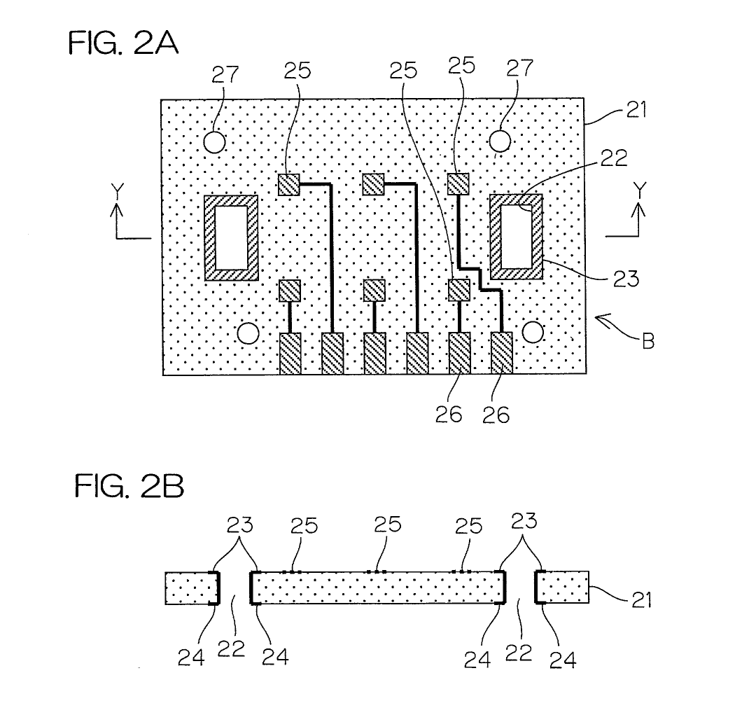

A wiring board will be then described on the basis of FIGS. 2A and 2B. A wiring board B has a dielectric board 21. A waveguide structure 22 penetrates the dielectric board 21 from its surface to its reverse surface. The cross-sectional shape of the waveguide structure 22 is the same as the cross-sectional opening shape of the high-frequency connecting pad 9. The waveguide structure 22 has its inner wall coated with a conductor. High-frequency connecting pads 23 and 24 are formed around the waveguide structure 22, respectively, on a surface and a reverse surface of the dielectric board 21. Further, a power pad 25 is formed on the surface of the dielectric board 21. The power pad 25, together with a low-frequency component such as a resistive element or a capacitor element which is carried on the wiring board B, constitutes a power circuit or a control circuit. The power circuit or the control circuit is finally connected to an external circuit via a connecting pad 26 (see FIG. 2A). Further, the dielectric board 21 is formed with a screw hole 27, used when the wiring board B is connected to an external circuit such as a waveguide or a plane antenna having a waveguide port, for screwing the external circuit.

3. Structure in which Wiring Substrate A is Mounted on Wiring Board B

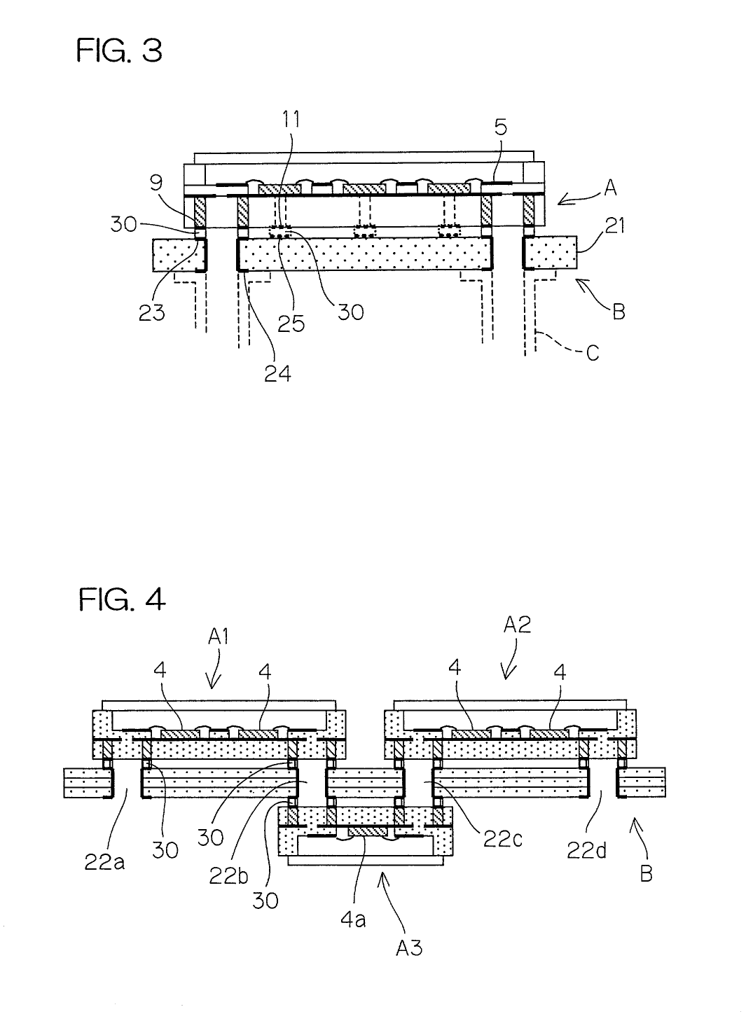

FIG. 3 is a schematic sectional view in a case where the wiring substrate A shown in FIG. 1 is mounted on the wiring board B shown in FIG. 2. As shown in FIG. 3, the high-frequency connecting pad 9 on the side of the wiring substrate A and the high-frequency connecting pad 23 on the side of the wiring board B are electrically connected to each other by a brazing material 30. Further, the power pad 11 on the side of the wiring substrate A and the power pad 25 on the side of the wiring board B are electrically connected to each other by the brazing material 30.

According to such a mounting structure, the wiring substrate A and the wiring board B can be connected to each other by a waveguide mode in the waveguide structure 22. They are connected to each other by the waveguide mode, as compared with the conventional connection by a microstripe line, a coplanar line, or the like. Accordingly, the transmission characteristics of the waveguide mode are determined irrespective of the dielectric characteristics of the dielectric board 21. Even if the dielectric board 21 in the wiring board B is formed of a material having bad frequency characteristics, for example, an insulating material containing organic resin as an ingredient, for example, glass epoxy, it is possible to make lossless transmission of a high-frequency signal.

According to the mounting structure, a waveguide C can be brazed to the high-frequency connecting pad 24 on the reverse surface of the wiring board B. Consequently, the wiring substrate A and an external circuit such as a plane antenna having the waveguide C can be coupled to each other through the wiring board B.

According to the mounting structure, it is possible to carry only the high-frequency component on the wiring substrate A, and mount the other low-frequency components on the surface and the reverse surface of the wiring board B, for example. Consequently, the wiring substrate A on which the high-frequency component is carried can be made smaller in size, as compared with that in a case where the high-frequency component and the low-frequency component are carried in the wiring substrate A, as in the conventional example, thereby making it possible to increase the density of the wiring substrate A. Further, the miniaturization of the wiring substrate A makes it possible to decrease the cost of a module and the mounting reliability thereof.

4. Structure in which a Plurality of Wiring Substrates A are Mounted on Wiring Board B

A mounting structure using a plurality of wiring substrates A1 and A2 will be described using a schematic sectional view of FIG. 4. According to the mounting structure shown in FIG. 4, at least four waveguide structures 22a, 22b, 22c, and 22d are formed in the wiring board B. The wiring substrate A1 and the wiring substrate A2 are mounted on an upper surface of the wiring board B, as in FIG. 3, respectively, with respect to the waveguide structures 22a and 22b and the waveguide structures 22c and 22d. Further, a wiring substrate A3 is mounted on the waveguide structures 22b and 22c in the wiring board B from the reverse surface of the wiring board B.

In such a mounting structure, the wiring substrate A1 and the wiring substrate A3 can be coupled to each other through the waveguide structure 22b formed in the wiring board B. The wiring substrate A3 and the wiring substrate A2 can be coupled to each other through the waveguide structure 22c formed in the wiring board B. The wiring substrates A1, A2, and A3 are coupled to one another by a waveguide mode. Accordingly, the transmission loss of a signal can be reduced without being affected by the dielectric characteristics of a dielectric material for the wiring board B.

Furthermore, the wiring substrate can be divided into a plurality of blocks. Accordingly, it is possible to improve mounting the reliability by miniaturizing each of the blocks.

In the above-mentioned mounting structure, ends of the waveguide structures 22a and 22d are further connected to another high-frequency component, antenna, or the like via another wiring substrate, waveguide, or the like.

In the mounting structure, the wiring substrate A3 which performs the function of connecting the two wiring substrates A1 and A2 need not necessarily have a power line, a control line, or a power pad, as shown in FIGS. 1A to 1C. A high-frequency component denoted by reference numeral 4a in the wiring substrate A3 may be a conversion section for connecting stripe conductors for output and input signals in the wiring substrate A3 to each other, for example.

5. Another Embodiment

Although a case where the cross-sectional shape of the waveguide structure in the wiring board B is a square is illustrated in the above-mentioned embodiment described in the items 1 to 4, the cross-sectional shape of the waveguide structure may be a circle. Particularly when the cross-sectional shape is a circle, a dielectric board can be easily processed by a drill. The waveguide structure has the merits of having a smooth processed surface and being good as a waveguide. Further, when the waveguide structure is formed in a circular shape, the shape of the opening 8 in the high-frequency connecting pad 9 in the wiring substrate A may be either a circle or a square. However, it is desirably a circle.

Examples of a dielectric material forming the dielectric substrate 1 in the wiring substrate A and the dielectric board 21 in the wiring board B include a ceramic material mainly composed of Al₂O₃, AlN, Si₃N₄, or mullite, a glass ceramic material formed by sintering glass or a mixture of glass and ceramic filler, an organic resin material such as epoxy resin, polyimide resin, or fluororesin such as Teflon, and an organic resin-ceramic (including glass) composite material.

Particularly, a suitable example of the dielectric substrate 1 in the wiring substrate A on which the high-frequency component is carried is one which has a small dielectric loss tangent and can be hermetically sealed. An example of a particularly desirable dielectric material is at least one type of inorganic material selected from a group consisting of alumina, AlN, and a glass ceramic material. If the dielectric substrate 1 is composed of such a hard material, it is possible to hermetically seal the carried high-frequency component, which is preferable in order to increase reliability.

As the dielectric board 21 in the wiring board B, all dielectric materials can be used because the high-frequency transmission characteristics thereof are not affected by the dielectric characteristics of the dielectric board 21 according to the present invention. Consequently, the dielectric material which is as low as possible may be used. From such a point, a suitable example of an insulating metal containing organic resin and particularly, at least one type selected from a group consisting of glass cloth-fluorine resin, glass cloth-epoxy resin, and alamide cloth-epoxy resin. Such an insulating material containing organic resin is low in cost, and is easily subjected to processing of a screw hole or the like. Accordingly, it can be fixed to an external circuit such as a waveguide or an antenna by a screw, which is preferable in that the cost is reduced, and connection to the external circuit is easy.

The difference in thermal expansion coefficients at room temperature between dielectric material of the wiring board B and dielectric material of the wiring substrate A is preferably not more than 10×10⁻⁶/K.

As the most suitable combination, it is the most desirable in terms of performance and cost that the dielectric substrate 1 in the wiring substrate A is composed of alumina ceramics or a glass ceramic material, the dielectric board 21 in the wiring board B is composed of glass cloth-epoxy resin.

### 6. EXAMPLE

The following experiments were conducted in order to confirm the effect of the present invention.

First, as a wiring substrate A, a substrate for evaluation which is similar to the wiring substrate A shown in FIG. 1 was fabricated by a normal stacking and simultaneous sintering technique using a green sheet composed of alumina ceramics (if the green sheet is sintered, the dielectric loss tangent at a frequency of 10 GHz is 0.0006) and tungsten metallized ink.

In the substrate for evaluation, there is no cavity in the wiring substrate A shown in FIG. 1, no high frequency component is carried thereon, and two microstrip lines each having an opened terminal end for input and output signals are connected to each other. An example of a matching section was one having a structure of a microstrip line 5, a slot hole 13, and a matching section 15 as shown in FIGS. 1A to 1C. After sintering, metallized surfaces of a surface and a reverse surface of a dielectric substrate were subjected to plating processing using nickel and gold.

The wiring board B shown in FIG. 2 was fabricated using a glass epoxy printed board FR-4 (the dielectric loss tangent at 10 GHz is 0.023) After the printed board was formed with an opening in cross section of a waveguide by a drill, and an inner surface of the opening was subjected to copper plating processing, to form a waveguide structure. Further, a high-frequency connecting pad, a power pad, or the like on the surface and the reverse surface of the printed board were formed by patterning copper foil.

Tin, silver, and copper solder paste was printed on a pad of the above-mentioned printed board by a printing method, the wiring board for evaluation was solder-mounted thereon by a reflow method, to obtain a sample for evaluation.

A waveguide for measurement was connected to the sample for evaluation, and an insertion loss at a frequency of 76 GHz was measured, to measure a connection loss from a microstrip line in the wiring substrate to the opening of the waveguide in the wiring board. As a result, it is confirmed that the connection loss at 76 GHz was approximately 0.4 dB, which is a practical and sufficiently small loss in fabricating a module.

Although the present invention has been described and illustrated in detail, it is clearly understood that the same is by way of illustration and example only and is not to be taken by way of limitation, the spirit and scope of the present invention being limited only by the terms of the appended claims.

1. A wiring substrate having a dielectric substrate having a high-frequency component and a transmission line formed on its surface,
said dielectric substrate being formed with an opening in a predetermined cross-sectional shape,
a high-frequency connecting pad coated with a conductor layer around said opening being formed on a reverse surface of said dielectric substrate,
a power pad being formed on the reverse surface of the dielectric substrate to be connected with the power line formed on the surface of the dielectric substrate,
a matching section for high-frequency coupling said transmission line and a waveguide structure connected to said high-frequency connecting pad to each other being formed in said opening.

2. The wiring substrate according to claim 1, wherein
said high-frequency connecting pad is connected to the waveguide structure by a brazing material.

3. The wiring substrate according to claim 1, wherein
a cover for hermetically sealing said high-frequency component is attached to the surface of said dielectric substrate.

4. The wiring substrate according to claim 1, wherein
the conductor layer in said high-frequency connecting pad is hollowed inward from the reverse surface of the dielectric substrate.

5. The wiring substrate according to claim 1, wherein
two or more high-frequency connecting pads are formed on the reverse surface of said dielectric substrate.

6. The wiring substrate according to claim 1, wherein
said transmission line is a microstrip line, and
said matching section comprises a microstrip line having an opened terminal end, a slot hole formed in a ground layer for the microstrip line, and a dielectric provided below the slot hole.

7. The wiring substrate according to claim 6, wherein
said slot hole is formed at the center of the opening of said high-frequency connecting pad,
a vertical conductor for connecting said ground layer and said high-frequency connecting pad is formed along said opening, and
said matching section is formed in a region enclosed by the vertical conductor.

8. The wiring substrate according to claim 1, wherein
said dielectric substrate is composed of ceramics.

9. The wiring substrate according to claim 1, wherein
said wiring substrate being mounted on a predetermined wiring board by connecting said high-frequency and power pads to the wiring board by a brazing material.

10. A wiring board comprising:
a dielectric board;
a waveguide structure penetrating the dielectric board from its surface to its reverse surface, having a predetermined cross-sectional opening shape, and having its inner wall coated with a conductor; and
a high-frequency connecting pad provided around said waveguide structure on the surface of said dielectric board.

11. A wiring substrate mounting structure in which a wiring substrate is placed on a surface of a wiring board, wherein
said wiring board comprises a waveguide structure penetrating a dielectric board from its surface to its reverse surface, having a predetermined cross-sectional opening shape, and having its inner wall coated with a conductor, and a high-frequency connecting pad provided around said waveguide structure on the surface of said dielectric board,
said wiring substrate has a dielectric substrate having a high-frequency component and a transmission line formed on its surface, said dielectric substrate being formed with an opening in a predetermined cross-sectional shape, a high-frequency connecting pad being formed around said opening on a reverse surface of said dielectric substrate, and a matching section for high-frequency coupling said transmission line and the waveguide structure to each other being formed in said opening, and
the high-frequency connecting pad in said wiring substrate and the high-frequency connecting pad in said wiring board are connected to each other.

12. The wiring substrate mounting structure according to claim 11, wherein
the dielectric substrate in said wiring substrate is composed of a ceramics insulating material, and
the dielectric board in said wiring board is composed of an insulating material containing organic resin.

13. The wiring substrate mounting structure according to claim 11, wherein
a high-frequency component is carried on said wiring substrate, and
a low-frequency component is carried on said wiring board.

14. The wiring substrate mounting structure according to claim 11, wherein
a conductor layer having the same opening shape as the opening shape of a waveguide is formed on a reverse surface of said wiring board.

15. The wiring substrate mounting structure according to claim 11, wherein
the dielectric board in said wiring board is formed with a screw hole for screwing an external circuit.

16. The wiring substrate mounting structure according to claim 11, wherein
the difference in coefficients of thermal expansion at room temperature to a temperature of 300° C. between the dielectric substrate in said wiring substrate and the dielectric board in the wiring board is not more than 10×10⁻⁶/K.

17. The wiring substrate mounting structure according to claim 11, wherein
a high frequency signal is transmitted to an external circuit having a waveguide port via the waveguide structure in said wiring board.

18. The wiring substrate mounting structure according to claim 11, wherein
another wiring substrate is mounted on the reverse surface of said wiring board.

19. A wiring substrate mounting structure, wherein
a plurality of wiring substrates having high-frequency components respectively carried thereon are mounted on a surface of a wiring board, and another wiring substrate is mounted on a reverse surface of said wiring board,
said wiring board comprises at least two waveguide structures each penetrating a dielectric board from its surface to its reverse surface, having a predetermined cross-sectional opening shape, and having its inner wall coated with a conductor, and high-frequency connecting pads respectively provided around said waveguide structures on the surface and the reverse surface of said dielectric board,
each of said wiring substrates mounted on the surface of said wiring board has a dielectric substrate having a high-frequency component and a transmission line formed on its surface, said dielectric substrate being formed with an opening in a predetermined cross-sectional shape, a high-frequency connecting pad coated with a conductor layer around said opening being formed on a reverse surface of said dielectric substrate, and a matching section for high-frequency coupling said transmission line and the waveguide structure to each other being formed in said opening, and
said wiring substrate mounted on the reverse surface of said wiring board has a dielectric substrate having a transmission line formed therein, said dielectric substrate being formed with two openings in a predetermined cross-sectional shape, a high-frequency connecting pad coated with a conductor layer around each of said openings being formed on the surface of said dielectric substrate, and a matching section for high-frequency coupling said transmission line and the waveguide structure to each other being formed in each of said openings, and
the openings of the wiring substrates mounted on the surface of the wiring board are respectively coupled to said two waveguide structures on the surface of said wiring board, and the opening of the wiring board mounted on the reverse surface of said wiring board is coupled to said two waveguide structures on the reverse surface of the wiring board.
